(19) United States
(12) Patent Application Publication
(10) Pub. No.: US 2025/0232827 A1
(43) Pub. Date: Jul. 17, 2025

(54) ENDURANCE EVALUATION TOOL FOR A MEMORY SUB-SYSTEM

(71) Applicant: Micron Technology, Inc., Boise, ID (US)

(72) Inventor: Luca Bert, Bologna (IT)

(21) Appl. No.: 19/014,100

(22) Filed: Jan. 8, 2025

Related U.S. Application Data
(60) Provisional application No. 63/620,560, filed on Jan. 12, 2024.

(51) Int. Cl. G11C 29/08; G06F 12/02

(52) U.S. Cl. CPC G11C 29/08; G06F 12/0246

(57) ABSTRACT

An endurance evaluation tool for a memory sub-system generates a simulated workload for the memory sub-system, the simulated workload comprising a series of input/output (I/O) commands directed to respective logical block addresses associated with the memory sub-system. The endurance evaluation tool further associates the respective logical block addresses with files in a file system, and issues the series of input/output commands to the memory sub-system to cause the memory sub-system to perform corresponding memory access operations on data representing the files in the file system.

### RELATED APPLICATIONS

This application claims the benefit of U.S. Provisional Patent Application No. 63/620,560, filed Jan. 12, 2024, the entire contents of which are hereby incorporated by reference herein.

### TECHNICAL FIELD

Embodiments of the disclosure relate generally to memory sub-systems, and more specifically, relate to an endurance evaluation tool for a memory sub-system.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The present disclosure will be understood more fully from the detailed description given below and from the accompanying drawings of various embodiments of the disclosure.

FIG. 1 illustrates an example computing system that includes a memory sub-system in accordance with some embodiments of the present disclosure.

FIG. 2 is a block diagram of an endurance evaluation tool implementing a file system in accordance with some embodiments of the present disclosure.

FIG. 3 is a flow diagram of an example method of endurance evaluation of a memory subsystem using a file system in accordance with some embodiments of the present disclosure.

FIG. 4 is a diagram illustrating the improved logical to physical mapping information for an endurance evaluation tool implementing a file system in accordance with some embodiments of the present disclosure.

FIG. 5 is a block diagram of an example computer system in which embodiments of the present disclosure may operate.

### DETAILED DESCRIPTION

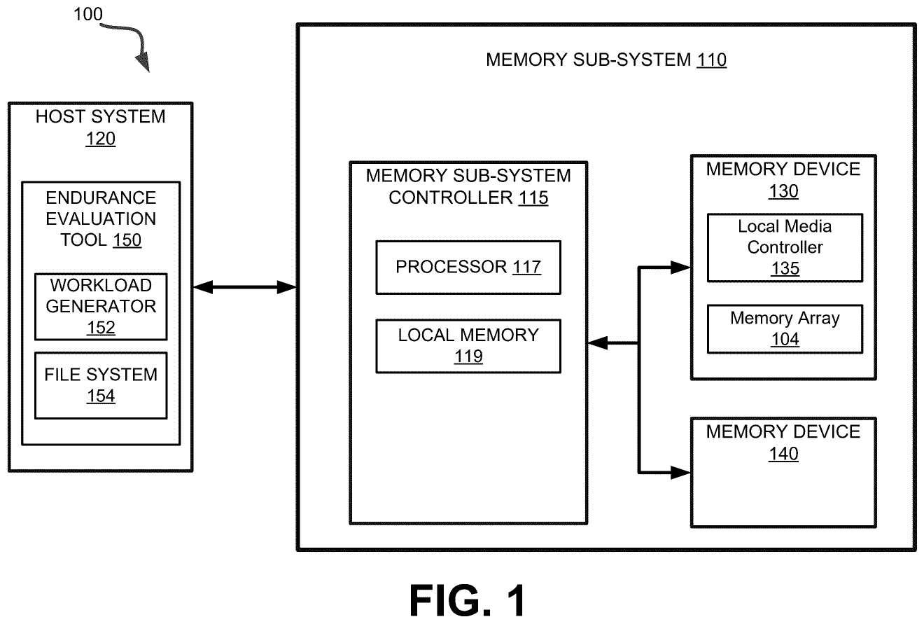

Aspects of the present disclosure are directed to an endurance evaluation tool for a memory sub-system. A memory sub-system can be a storage device, a memory module, or a hybrid of a storage device and memory module. Examples of storage devices and memory modules are described below in conjunction with FIG. 1. In general, a host system can utilize a memory sub-system that includes one or more components, such as memory devices that store data. The host system can provide data to be stored at the memory sub-system and can request data to be retrieved from the memory sub-system.

A memory sub-system can include high density non-volatile memory devices where retention of data is desired when no power is supplied to the memory device. For example, NAND memory, such as 3D flash NAND memory, offers storage in the form of compact, high density configurations. A non-volatile memory device is a package of one or more dice, each including one or more planes. For some types of non-volatile memory devices (e.g., NAND memory), each plane includes of a set of physical blocks. Each block includes of a set of pages. Each page includes of a set of memory cells (“cells”). A cell is an electronic circuit that stores information. Depending on the cell type, a cell can store one or more bits of binary information, and has various logic states that correlate to the number of bits being stored. The logic states can be represented by binary values, such as “0” and “1”, or combinations of such values.

A memory device can be made up of bits arranged in a two-dimensional or a three-dimensional grid. Memory cells are formed onto a silicon wafer in an array of columns (also hereinafter referred to as bitlines) and rows (also hereinafter referred to as wordlines). A wordline can refer to one or more rows of memory cells of a memory device that are used with one or more bitlines to generate the address of each of the memory cells. The intersection of a bitline and wordline constitutes the address of the memory cell. A block hereinafter refers to a unit of the memory device used to store data and can include a group of memory cells, a wordline group, a wordline, or individual memory cells. One or more blocks can be grouped together to form separate partitions (e.g., planes) of the memory device in order to allow concurrent operations to take place on each plane.

One example of a memory sub-system is a solid-state drive (SSD) that includes one or more non-volatile memory devices and a memory sub-system controller to manage the non-volatile memory devices. Certain memory sub-systems use a Flash Translation Layer (FTL) to translate logical addresses of memory access requests, often referred to as logical block addresses (LBAs), to corresponding physical memory addresses, which can be stored in one or more FTL mapping tables. In some instances, the FTL mapping table can be referred to as a logical-to-physical (L2P) mapping table storing L2P mapping information, at least a portion of which may be stored in volatile memory (e.g., Dynamic Random Access Memory (DRAM)) in the memory sub-system so that it can be accessed with minimal latency. During operation, the memory sub-system can receive one or more input/output (I/O) chunks of data (e.g., from a host system) to be stored. Each I/O chunk can be represented by a corresponding LBA and can have a fixed size (e.g., 4 kilobytes) that is set, for example, by the host system. The received data is then written to the non-volatile memory devices at corresponding physical memory addresses at a granularity referred to as a translation unit (TU). The translation unit is the base granularity of data managed by the memory sub-system and can include a predefined number of logical units (e.g., logical pages, logical blocks, etc.). Certain memory devices implement a translation unit size that is equal to the I/O chunk size (e.g., 4 kilobytes). When the translation unit is written to the physical memory address, the memory sub-system controller can create a corresponding entry in the L2P mapping table indicating the correlation between the LBA and the physical memory address. Thus, the L2P mapping table can include an entry for every translation unit written to the non-volatile memory device.

Memory sub-systems, such as SSDs, are expected to meet certain levels of performance (e.g., performance benchmarks), including with respect to endurance. The endurance of a memory sub-system represents how many program and erase cycles can be performed before the underlying storage media physically wears out. Certain types of non-volatile memory devices, such as those implemented using quad-level cell (QLC) memory, for example, are particularly susceptible to decreased endurance when write amplification is present. For example, the additional write operations can cause the non-volatile memory device to wear out much faster and suffer additional disturb errors, which hurts the lifetime and reliability of the memory sub-system. In order to ensure that a memory sub-stem can meet certain performance benchmarks, such as industry benchmarks or customer benchmarks, an endurance evaluation tool can be used to test the memory sub-system. The endurance evaluation tool can simulate a workload (i.e., a series of program and erase operations sent to random addresses) for the memory sub-system, so that the endurance of the memory sub-system in response to the workload can be measured. Typically the endurance evaluation tool generates the simulated workload using a default I/O chunk size (e.g., 4 kilobytes), as described above.

An endurance evaluation tool that functions in this manner has a number of deficiencies, however. The first is that in practice, most real-world applications issue write requests in much larger sizes than 4 kilobytes (e.g., tens or hundreds of kilobytes sent in tens or hundreds of I/O chunks). The second is that in practice, the series of program and erase operations are rarely sent to random addresses. Rather, the logical block addresses of the I/O chunks in a series of operations often correspond to a file and thus can be written and mapped together in concurrent entries in the L2P mapping table. Thus, when the file is deleted from the memory sub-system, the concurrent entries in the L2P mapping table can all be deleted together leaving a larger concurrent hole in the mapping information. The random logical block addresses written to by the endurance evaluation tool, however, may be deleted separately. For example, if only some of the random logical block addresses are deleted, the L2P mapping table can become fragmented, with multiple smaller separate holes in the mapping information.

Depending on the translation unit size, a fragmented L2P mapping table can significantly hurt the endurance of the memory sub-system. For example, if the translation unit size is greater than the I/O chunk size, write amplification in the memory sub-system can be increased. For example, if an I/O chunk of 4 kilobytes of host data is received, but the translation unit size being utilized is 16 kilobytes, the memory sub-system controller will read 16 kilobytes of data from the non-volatile memory device, modify 4 kilobytes of the read data, and write the full 16 kilobytes back to the non-volatile memory device. In such an example, an extra 12 kilobytes of identical data is read from and then written back to the non-volatile memory device in order to write the 4 kilobytes of new host data to the non-volatile memory device. This can be referred to as a write amplification factor of four (4). As discussed above, such an increased write amplification factor hurts the lifetime and reliability of the memory sub-system. In other implementations, the I/O chunk size may be different (e.g., 16 kilobytes, 64 kilobytes), and file system writes can be much larger (e.g., 100 kilobytes or more). Regardless of the specific size, the write amplification is present and can lead to the fragmentation issue described above.

Aspects of the present disclosure address the above and other deficiencies by implementing an improved endurance evaluation tool for a memory sub-system. The endurance evaluation tool simulates a workload (i.e., a series of program and erase operations) for a memory sub-system, so that the endurance of the memory sub-system in response to the workload can be measured. In one embodiment, the endurance evaluation tool utilizes a file system to structure the simulated workload to more closely approximate real-world conditions when evaluating the endurance of the memory sub-system. Thus, the program and erase commands that are generated by the endurance evaluation tool and sent to the memory sub-system specify individual files, as structured by the file system, rather than random logical block addresses of a given size (e.g., 4 kilobytes). The memory sub-system receives the program and erase commands, executes the corresponding operations, and updates the mapping information in the L2P mapping table accordingly.

Advantages of the approach described herein include, but are not limited to, improved performance of the endurance evaluation tool. The structure imposed on the simulated workload by the file system more closely approximates real-world conditions than a sequence of truly random logical block addresses. Thus, when a file is deleted from the memory sub-system, the corresponding entries in the L2P mapping table can all be deleted together leaving a larger concurrent hole in the mapping information, as opposed to the individual fragmented holes that would result when the data at individual logical block addresses is deleted separately. The less fragmented L2P mapping table reduces write amplification and increases the endurance of the memory sub-system. Accordingly, the improved endurance evaluation tool can more accurately measure the endurance of the memory sub-system, including when implementing quad-level cell memory, without using a simulated workload that artificially increases write amplification in the memory sub-system.

FIG. 1 illustrates an example computing system 100 that includes a memory sub-system 110 in accordance with some embodiments of the present disclosure. The memory sub-system 110 can include media, such as one or more volatile memory devices (e.g., memory device 140), one or more non-volatile memory devices (e.g., one or more memory device(s) 130), or a combination of such.

A memory sub-system 110 can be a storage device, a memory module, or a hybrid of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory modules (NVDIMMs).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some embodiments, the host system 120 is coupled to different types of memory sub-system 110. FIG. 1 illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 120 can include a processor chipset and a software stack executed by the processor chipset. The processor chipset can include one or more cores, one or more caches, a memory controller (e.g., NVDIMM controller), and a storage protocol controller (e.g., PCIe controller, SATA controller). The host system 120 uses the memory sub-system 110, for example, to write data to the memory sub-system 110 and read data from the memory sub-system 110.

The host system 120 can be coupled to the memory sub-system 110 via a physical host interface. Examples of a physical host interface include, but are not limited to, a serial advanced technology attachment (SATA) interface, a peripheral component interconnect express (PCIe) interface, universal serial bus (USB) interface, Fibre Channel, Serial Attached SCSI (SAS), a double data rate (DDR) memory bus, Small Computer System Interface (SCSI), a dual in-line memory module (DIMM) interface (e.g., DIMM socket interface that supports Double Data Rate (DDR)), etc. The physical host interface can be used to transmit data between the host system 120 and the memory sub-system 110. The host system 120 can further utilize an NVM Express (NVMe) interface to access the memory components (e.g., the one or more memory device(s) 130) when the memory sub-system 110 is coupled with the host system 120 by the PCIe interface. The physical host interface can provide an interface for passing control, address, data, and other signals between the memory sub-system 110 and the host system 120. FIG. 1 illustrates a memory sub-system 110 as an example. In general, the host system 120 can access multiple memory sub-systems via a same communication connection, multiple separate communication connections, and/or a combination of communication connections.

The memory devices 130, 140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device(s) 130) include negative-and (NAND) type flash memory and write-in-place memory, such as three-dimensional cross-point (“3D cross-point”) memory. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory device(s) 130 can include one or more arrays of memory cells. One type of memory cell, for example, single level cells (SLC) can store one bit per cell. Other types of memory cells, such as multi-level cells (MLCs), triple level cells (TLCs), and quad-level cells (QLCs), can store multiple bits per cell. In some embodiments, each of the memory devices 130 can include one or more arrays of memory cells such as SLCs, MLCs, TLCs, QLCs, or any combination of such. In some embodiments, a particular memory device can include an SLC portion, and an MLC portion, a TLC portion, or a QLC portion of memory cells. The memory cells of the memory devices 130 can be grouped as pages that can refer to a logical unit of the memory device used to store data. With some types of memory (e.g., NAND), pages can be grouped to form blocks.

Although non-volatile memory components such as a 3D cross-point array of non-volatile memory cells and NAND type flash memory (e.g., 2D NAND, 3D NAND) are described, the memory device 130 can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), negative-or (NOR) flash memory, electrically erasable programmable read-only memory (EEPROM).

A memory sub-system controller 115 (or controller 115 for simplicity) can communicate with the memory device(s) 130 to perform operations such as reading data, writing data, or erasing data at the memory devices 130 and other such operations. The memory sub-system controller 115 can include hardware such as one or more integrated circuits and/or discrete components, a buffer memory, or a combination thereof. The hardware can include a digital circuitry with dedicated (i.e., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can include a processor 117 (e.g., a processing device) configured to execute instructions stored in a local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some embodiments, the local memory 119 can include memory registers storing memory pointers, fetched data, etc. The local memory 119 can also include read-only memory (ROM) for storing micro-code. While the example memory sub-system 110 in FIG. 1 has been illustrated as including the memory sub-system controller 115, in another embodiment of the present disclosure, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory device(s) 130. The memory sub-system controller 115 can be responsible for other operations such as wear leveling operations, garbage collection operations, error detection and error-correcting code (ECC) operations, encryption operations, caching operations, and address translations between a logical address (e.g., logical block address (LBA), namespace) and a physical address (e.g., physical block address) that are associated with the memory device(s) 130. The memory sub-system controller 115 can further include host interface circuitry to communicate with the host system 120 via the physical host interface. The host interface circuitry can convert the commands received from the host system into command instructions to access the memory device(s) 130 as well as convert responses associated with the memory device(s) 130 into information for the host system 120.

The memory sub-system 110 can also include additional circuitry or components that are not illustrated. In some embodiments, the memory sub-system 110 can include a cache or buffer (e.g., DRAM) and address circuitry (e.g., a row decoder and a column decoder) that can receive an address from the memory sub-system controller 115 and decode the address to access the memory device(s) 130.

In some embodiments, the memory device(s) 130 include local media controllers 135 that operate in conjunction with memory sub-system controller 115 to execute operations on one or more memory cells of the memory device(s) 130. An external controller (e.g., memory sub-system controller 115) can externally manage the memory device 130 (e.g., perform media management operations on the memory device(s) 130). In some embodiments, a memory device 130 is a managed memory device, which is a raw memory device (e.g., memory array 104) having control logic (e.g., local controller 135) for media management within the same memory device package. An example of a managed memory device is a managed NAND (MNAND) device. Memory device(s) 130, for example, can each represent a single die having some control logic (e.g., local media controller 135) embodied thereon. In some embodiments, one or more components of memory sub-system 110 can be omitted.

In one embodiment, computing system 100 includes endurance evaluation tool 150. For example, endurance evaluation tool 150 may be embodied on host system 120, or on some other component that is communicably coupled with memory sub-system 110. In one embodiment, the endurance evaluation tool 150 includes a workload generator 152 and a file system 154, among other components which are not shown. Workload generator 152 generates a workload (i.e., a series of program and erase operations) to be applied to memory sub-system 110, so that the endurance of the memory sub-system 110 can be measured in response to the workload. In one embodiment, the endurance evaluation tool 150 utilizes file system 154 to structure the simulated workload to more closely approximate real-world conditions when evaluating the endurance of the memory sub-system 110. For example, rather than being directed to random logical block addresses, the program and erase commands that are generated by workload generator 152 specify individual files, as structured by the file system 154, which can then be applied to memory sub-system 110. The memory sub-system 110 receives the program and erase commands, executes the corresponding operations, and updates mapping information in a L2P mapping table accordingly. Further details with regard to the operations of endurance evaluation tool 150 are described below.

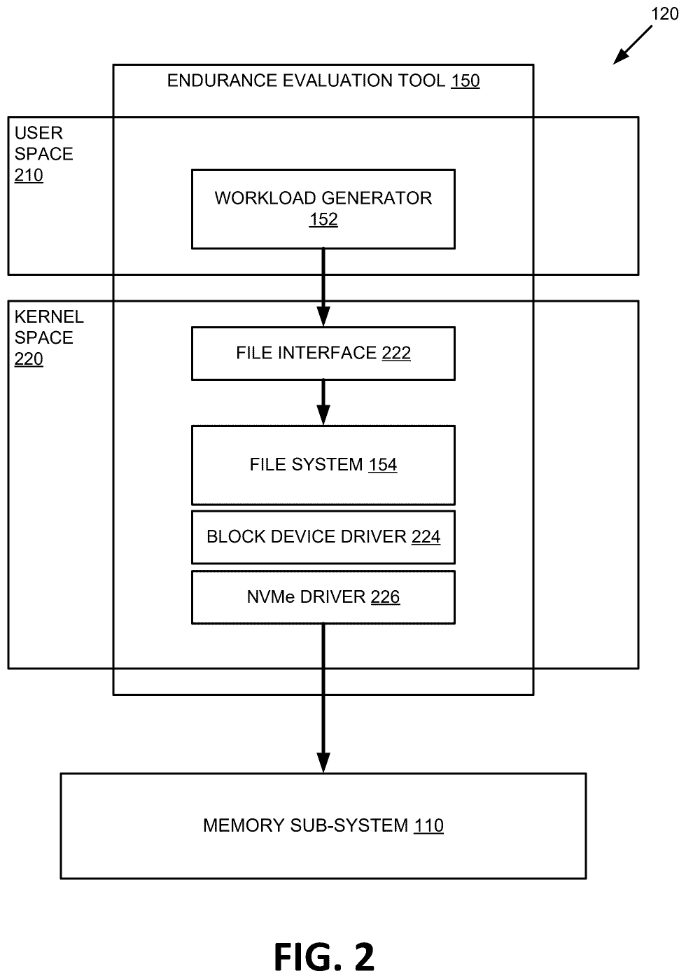

FIG. 2 is a block diagram of an endurance evaluation tool implementing a file system in accordance with some embodiments of the present disclosure. As described above, in one embodiment, endurance evaluation tool 150 executes on host system 120. In other embodiments, however, endurance evaluation tool 150 can execute on some other computing device or system that is communicably coupled with memory sub-system 110. In one embodiment, components of the endurance evaluation tool 150 span both a user space 210 and a kernel space 220 of the host system 120. For example, the workload generator 152 may execute in the user space 210, while a file interface 222, the file system 154, a block device driver 224, and an NVMe driver 226 may execute in the kernel space 220. In other implementations, the endurance evaluation tool 150 may include different and/or additional components, and the illustrated and/or additional components may potentially be arranged differently across the user space 210 and the kernel space 220.

Workload generator 152 generates a workload (i.e., a series of program and erase operations) to be applied to memory sub-system 110. Workload generator 152 can be configured according to various configuration settings (e.g., to adjust the values of various parameters) in order to control the simulated workload. These adjustable configuration settings can include, for example, the type of I/O operations to be generated (e.g., read, program, erase), the ratio of different types of I/O operations relative to one another, block sizes, access patterns (e.g., sequential or random), etc. For example, in a random workload, the I/O operations generated by workload generator 152 can include a mix of program and erase operations, each directed to a corresponding logical block address in the memory sub-system 110. Workload generator 152 can provide this sequence of I/O operations to file interface 222.

File interface 222 can include a set of functions, commands, or system calls that allow applications in user space 210, such as workload generator 152, to interact with file system 154 in the kernel space 220. Upon receiving the sequence of I/O operations from workload generator 152, file interface 222 can organize the corresponding logical block addresses into one or more files in file system 154. Organization of the one or more files can include creating the files themselves, creating one or more directories that organize the files into a hierarchy for file management, generating metadata associated with the files and directories (e.g., including file attributes such as name, size, permissions, etc.), and/or creating associated allocation tables and indexes that manage how the data from the files and directories is stored on the underlying memory sub-system 110.

In one embodiment, file system 154 is a log-structured file system that organizes and manages data stored on memory sub-system 110 using logs, where changes or modifications to the files and metadata are written sequentially as a series of records or segments. For example, such a log-structured file system may be optimized for sequential writes by appending all changes to new blocks in a log-like structure, rather than overwriting existing data. The blocks (i.e., segments) in the log are written sequentially, and once full, can be written to the memory sub-system 110 as a whole segment. In one embodiment, file system 154 is a an open source file system, such as Ext4 or XFS, for example. In other embodiments, some other type of file system can be used.

Block device driver 224 serves as an intermediary between the file system 224 and the memory sub-system 110 and can manages I/O operations. Block device driver 224 generates I/O requests corresponding to the files of file system 224, for example, to program or erase the corresponding data from the physical locations on the memory device of memory sub-system 110. The I/O requests can be sent by NVMe driver 226 over a communications bus (e.g., a PCIe bus) to memory sub-system 110.

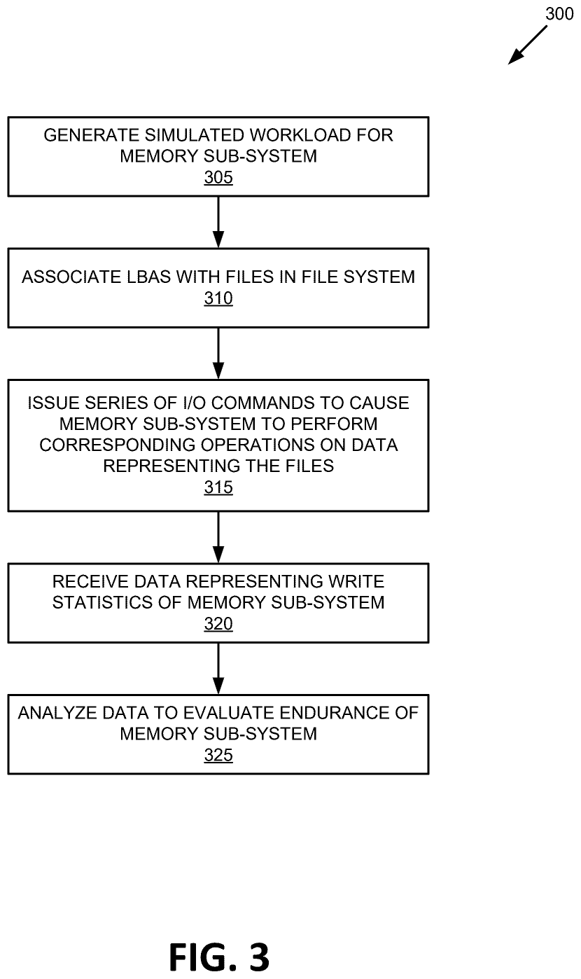

FIG. 3 is a flow diagram of an example method of endurance evaluation of a memory subsystem using a file system in accordance with some embodiments of the present disclosure. The method 300 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 300 is performed by the endurance evaluation tool 150 of FIG. 1. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 305, the processing logic (e.g., the endurance evaluation tool 150) generates a simulated workload for a memory sub-system, such as memory sub-system 110. For example, the workload generator 152 of endurance evaluation tool 150 can generate a series of input/output (I/O) commands directed to respective logical block addresses associated with the memory sub-system 110. Depending on the configuration settings, the series of I/O commands can include, for example, a mix of read, program, and erase commands, where each command is directed to a corresponding logical block address. Upon generation of the simulated workload, workload generator 152 can provide this sequence of I/O operations to file interface 222.

At operation 310, the processing logic associates the respective logical block addresses with files in a file system, such as file system 154. In one embodiment, upon receiving the sequence of I/O operations from workload generator 152, file interface 222 can organize the corresponding logical block addresses into one or more files in file system 154. Organization of the one or more files can include creating the files themselves, creating one or more directories that organize the files into a hierarchy for file management, generating metadata associated with the files and directories (e.g., including file attributes such as name, size, permissions, etc.), and/or creating associated allocation tables and indexes that manage how the data from the files and directories is stored on the underlying memory sub-system 110. In one embodiment, file system 154 is an open source, log-structured file system that organizes and manages data stored on memory sub-system 110 using logs, where changes or modifications to the files and metadata are written sequentially as a series of records or segments. In other embodiments, some other type of file system can be used.

At operation 315, the processing logic issues the series of input/output commands to the memory sub-system to cause the memory sub-system to perform corresponding memory access operations on data representing the files in the file system. In one embodiment, block device driver 224 generates I/O requests corresponding to the files of file system 224, for example, to program or erase the corresponding data from the physical locations on the memory device 130 of memory sub-system 110. The I/O requests can be sent by NVMe driver 226 over a communications bus (e.g., a PCIe bus) to memory sub-system 110. In one embodiment, the series of I/O commands, and the corresponding I/O requests, includes at least one program command to program data associated with a file to the memory sub-system 110 and at least one erase command to erase at least a portion of the data associated with the file from the memory sub-system 110.

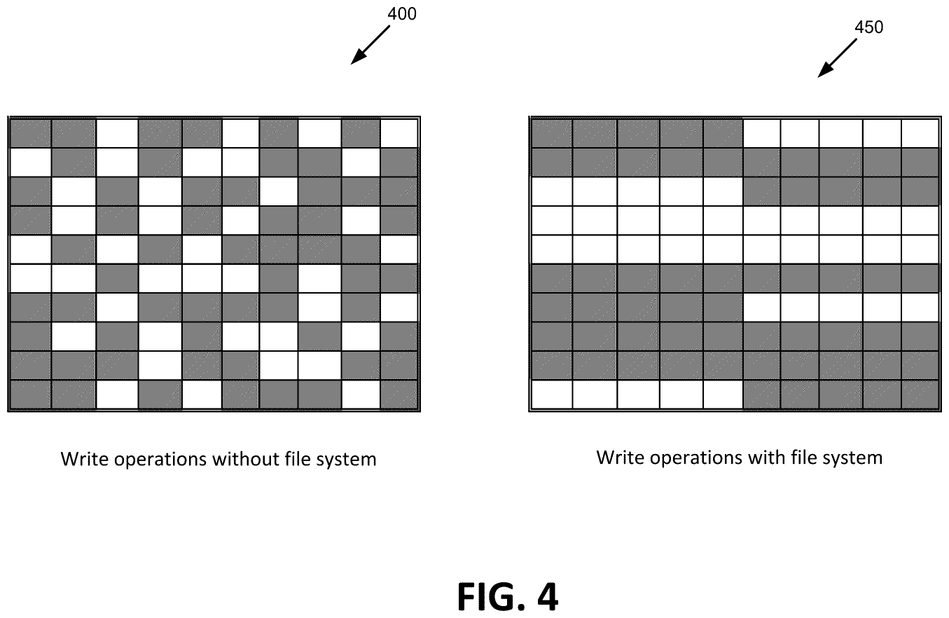

In one embodiment, responsive to receiving the program command, the memory sub-system is to write the received data to memory device 130 at corresponding physical memory addresses using a granularity referred to as a translation unit (TU). The translation unit is the base granularity of data managed by the memory sub-system 110 and can include a predefined number of logical units (e.g., logical pages, logical blocks, etc.). Certain memory devices implement a translation unit size that is equal to the I/O chunk size (e.g., 4 kilobytes). In addition, the memory sub-system 110 is to generate a plurality of entries in an address mapping table to map the respective logical block addresses associated with the file to physical addresses where the data is stored on the memory sub-system 110. An example of logical to physical mapping information in an address mapping table is illustrated in FIG. 4. When a translation unit is written to the physical memory address, the memory sub-system controller 115 can create a corresponding entry in the L2P mapping table indicating the correlation between the LBA and the physical memory address. Thus, the L2P mapping table can include an entry for every translation unit written to the non-volatile memory device. The current entries in address mapping table 400 and 450 of FIG. 4 are shown as shaded boxes.

In one embodiment, responsive to receiving an erase command, the memory sub-system 110 is to erase at least a portion of the data associated with the file and delete at least a subset of the plurality of entries in the address mapping table. As noted above, when the logical block addresses of the I/O chunks in a series of operations are associated with a file, they can be written and mapped together in concurrent entries in the L2P mapping table. Thus, when the file is deleted from the memory sub-system, the concurrent entries in the L2P mapping table can all be deleted together leaving a larger concurrent hole in the mapping information, as shown in L2P mapping table 450 of FIG. 4. There, the shaded boxes represent the current entries and the empty boxes represent the entries that have been deleted. This is in contrast to L2P mapping table 400, which shows the result when random logical block addresses are deleted, causing the L2P mapping table 400 to become fragmented, with multiple smaller separate holes (empty boxes) in the mapping information.

At operation 320, the processing logic receives data representing write statistics of the memory sub-system 110 in response to performance of the corresponding memory access operations. The write statistics can include, for example, log data representing the number of program/erase cycles performed on various segments (e.g., superblocks, blocks, sub-blocks, cells) of the memory device 130, as well as the total amount of data written to the memory device 130. In other embodiments, endurance evaluation tool 150 can receive additional and/or different statistics from memory sub-system 110.

At operation 325, the processing logic analyzes the data representing the write statistics to evaluate an endurance of the memory sub-system 110. In one embodiment, endurance evaluation tool 150 compares the amount of data written to the memory device 130 to an amount of data that the host system 120 requested to be written. The ratio of these values represents the write amplification factor of the memory sub-system 110. If the write amplification factor is greater than one by less than some threshold amount, then endurance evaluation tool 150 can determine that the memory sub-system has satisfactory endurance. Conversely, if the write amplification factor is greater than one by more than some threshold amount, then endurance evaluation tool 150 can determine that the memory sub-system has unsatisfactory endurance. In other embodiments, endurance evaluation tool 150 can perform different and/or additional analysis of the memory sub-system 110.

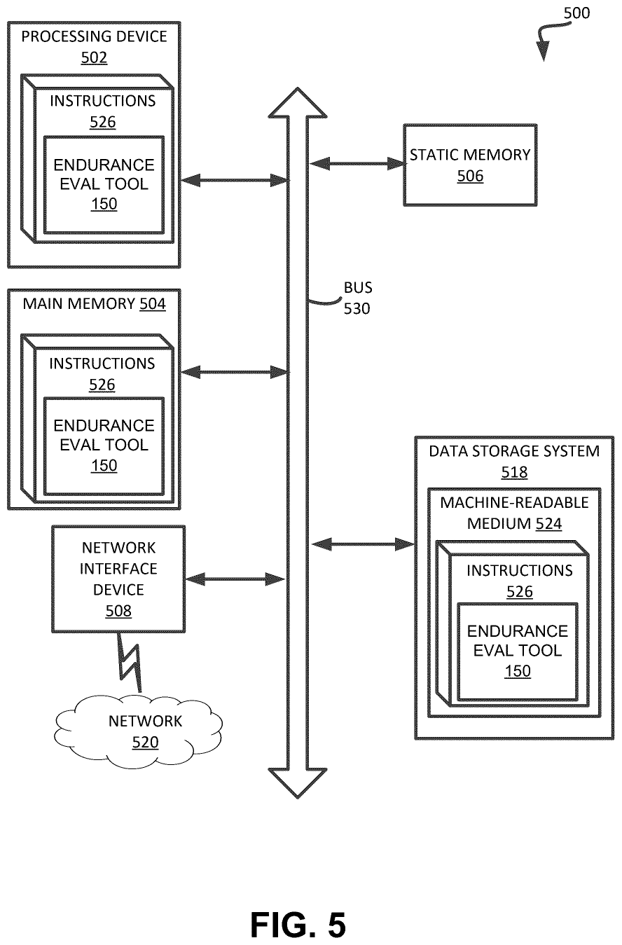

FIG. 5 illustrates an example machine of a computer system 500 within which a set of instructions, for causing the machine to perform any one or more of the methodologies discussed herein, can be executed. In some embodiments, the computer system 500 can correspond to a host system (e.g., the host system 120 of FIG. 1) that includes, is coupled to, or utilizes a memory sub-system (e.g., the memory sub-system 110 of FIG. 1) or can be used to perform the operations of a controller (e.g., to execute an operating system to perform operations corresponding to the endurance evaluation tool 150 of FIG. 1). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 500 includes a processing device 502, a main memory 504 (e.g., read-only memory (ROM), flash memory, dynamic random access memory (DRAM) such as synchronous DRAM (SDRAM) or Rambus DRAM (RDRAM), etc.), a static memory 506 (e.g., flash memory, static random access memory (SRAM), etc.), and a data storage system 518, which communicate with each other via a bus 530.

Processing device 502 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 502 can also be one or more special-purpose processing devices such as an application specific integrated circuit (ASIC), a field programmable gate array (FPGA), a digital signal processor (DSP), network processor, or the like. The processing device 502 is configured to execute instructions 526 for performing the operations and steps discussed herein. The computer system 500 can further include a network interface device 508 to communicate over the network 520.

The data storage system 518 can include a machine-readable storage medium 524 (also known as a computer-readable medium) on which is stored one or more sets of instructions 526 or software embodying any one or more of the methodologies or functions described herein. The instructions 526 can also reside, completely or at least partially, within the main memory 504 and/or within the processing device 502 during execution thereof by the computer system 500, the main memory 504 and the processing device 502 also constituting machine-readable storage media. The machine-readable storage medium 524, data storage system 518, and/or main memory 504 can correspond to the memory sub-system 110 of FIG. 1.

In one embodiment, the instructions 526 include instructions to implement functionality corresponding to the endurance evaluation tool 150 of FIG. 1). While the machine-readable storage medium 524 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMS, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A system comprising:
memory; and
a processing device, operatively coupled with the memory, to perform operations comprising:
generating a simulated workload for a memory sub-system, the simulated workload comprising a series of input/output (I/O) commands directed to respective logical block addresses associated with the memory sub-system;
associating the respective logical block addresses with files in a file system; and
issuing the series of input/output commands to the memory sub-system to cause the memory sub-system to perform corresponding memory access operations on data representing the files in the file system.

2. The system of claim 1, wherein the series of input/output commands comprises at least one program command to program data associated with a file to the memory sub-system and at least one erase command to erase at least a portion of the data associated with the file from the memory sub-system.

3. The system of claim 2, wherein responsive to receiving the program command, the memory sub-system is to generate a plurality of entries in an address mapping table to map the respective logical block addresses associated with the file to physical addresses where the data is stored on the memory sub-system.

4. The system of claim 3, wherein responsive to receiving the erase command, the memory sub-system is to delete at least a subset of the plurality of entries in the address mapping table.

5. The system of claim 1, wherein the processing device is to perform operations further comprising:
receiving data representing write statistics of the memory sub-system in response to performance of the corresponding memory access operations.

6. The system of claim 5, wherein the processing device is to perform operations further comprising:
analyzing the data representing the write statistics to evaluate an endurance of the memory sub-system.

7. The system of claim 1, wherein the file system comprises an open source, log-structured file system.

8. A method comprising:
generating a simulated workload for a memory sub-system, the simulated workload comprising a series of input/output (I/O) commands directed to respective logical block addresses associated with the memory sub-system;
associating the respective logical block addresses with files in a file system; and
issuing the series of input/output commands to the memory sub-system to cause the memory sub-system to perform corresponding memory access operations on data representing the files in the file system.

9. The method of claim 8, wherein the series of input/output commands comprises at least one program command to program data associated with a file to the memory sub-system and at least one erase command to erase at least a portion of the data associated with the file from the memory sub-system.

10. The method of claim 9, wherein responsive to receiving the program command, the memory sub-system is to generate a plurality of entries in an address mapping table to map the respective logical block addresses associated with the file to physical addresses where the data is stored on the memory sub-system.

11. The method of claim 10, wherein responsive to receiving the erase command, the memory sub-system is to delete at least a subset of the plurality of entries in the address mapping table.

12. The method of claim 8, further comprising:
receiving data representing write statistics of the memory sub-system in response to performance of the corresponding memory access operations.

13. The method of claim 12, further comprising:
analyzing the data representing the write statistics to evaluate an endurance of the memory sub-system.

14. The method of claim 8, wherein the file system comprises an open source, log-structured file system.

15. A non-transitory computer-readable storage medium comprising instructions that, when executed by a processing device, cause the processing device to perform operations comprising:
generating a simulated workload for a memory sub-system, the simulated workload comprising a series of input/output (I/O) commands directed to respective logical block addresses associated with the memory sub-system;
associating the respective logical block addresses with files in a file system; and
issuing the series of input/output commands to the memory sub-system to cause the memory sub-system to perform corresponding memory access operations on data representing the files in the file system.

16. The non-transitory computer-readable storage medium of claim 15, wherein the series of input/output commands comprises at least one program command to program data associated with a file to the memory sub-system and at least one erase command to erase at least a portion of the data associated with the file from the memory sub-system.

17. The non-transitory computer-readable storage medium of claim 16, wherein responsive to receiving the program command, the memory sub-system is to generate a plurality of entries in an address mapping table to map the respective logical block addresses associated with the file to physical addresses where the data is stored on the memory sub-system.

18. The non-transitory computer-readable storage medium of claim 17, wherein responsive to receiving the erase command, the memory sub-system is to delete at least a subset of the plurality of entries in the address mapping table.

19. The non-transitory computer-readable storage medium of claim 15, wherein the instructions cause the processing device to perform operations further comprising:
receiving data representing write statistics of the memory sub-system in response to performance of the corresponding memory access operations; and
analyzing the data representing the write statistics to evaluate an endurance of the memory sub-system.

20. The non-transitory computer-readable storage medium of claim 15, wherein the file system comprises an open source, log-structured file system.
